(19) United States
(12) Patent Application Publication
(10) Pub. No.: US 2017/0148970 A1
(43) Pub. Date: May 25, 2017

(54) ORGANIC THERMOELECTRIC COMPOSITES AND THEIR USES

(71) Applicant: The Texas A&M University System, College Station, TX (US)

(72) Inventors: Choongho Yu, College Station, TX (US); Jaime C. Grunlan, College Station, TX (US); Chungyeon Cho, Bryan, TX (US)

(21) Appl. No.: 15/315,516

(22) PCT Filed: Jun. 12, 2015
(86) PCT No.: PCT/US15/35636

§ 371 Date: Dec. 1, 2016

Related U.S. Application Data
(60) Provisional application No. 62/011,535, filed on Jun. 12, 2014.
(60) Provisional application No. 62/095,637, filed on Dec. 22, 2014.

(51) Int. Cl. H01L 35/24; F25B 21/02; H01L 35/32; H01L 23/38; H01L 35/02; H01L 35/34

(52) U.S. Cl. CPC H01L 35/24; H01L 35/02; H01L 35/34; H01L 35/32; H01L 23/38; F25B 21/02

(57) ABSTRACT

Embodiments of the invention are directed to conducting polymers are used to produce polymer composites through the addition of graphitic carbon. The concentration of graphitic carbons such as carbon nanotubes is low enough to produce many non-percolated networks of graphitic carbons. Potential commercial applications include self-powered energy harvesting units operated by any type and grade heat including body heat and waste heat. Embodiments of the invention are also directed to a process for a thermoelectric nanocomposite thin film comprising organic conducting polymers and organic conducting nanomaterials.

### CROSS-REFERENCES TO RELATED APPLICATIONS

This application claims the benefit of U.S. Provisional Patent Application Ser. No. 62/011,535 filed Jun. 12, 2014, and U.S. Provisional Patent Application Ser. No. 62/095,637 filed Dec. 22, 2014, each of which is incorporated herein by reference in its entirety.

### STATEMENT OF FEDERALLY SPONSORED RESEARCH OR DEVELOPMENT

This invention was made with government support under Grant No. FA9550-09-1-0609 awarded by the Air Force Office of Scientific Research and Grant No. 1030958 awarded by the National Science Foundation. The government has certain rights in the invention.

### TECHNICAL FIELD

Embodiments of the invention are directed to organic thermoelectric compositions and their uses. In particular, the invention relates to multilayer films produced from organic thermoelectric compositions.

### BACKGROUND OF THE INVENTION

Electrical energy can be harvested from thermal energy including low-grade heat, waste heat, and body heat, which are typically lost to the environment without producing useful work. Temperature gradients are commonly produced by the environment (e.g., geothermal energy) or may be man-made by the countless systems that consume power (e.g., combustion engines, home appliances, etc.). These gradients are generally too small for conventional systems to adequately harvest energy from. However, thermoelectric materials have the ability to convert any temperature gradient into useful electricity. In order to harness this energy, an electrical current is created from the waste heat by the diffusion of charge carriers (i.e., electrons or holes) through the material from the hot side to the cold, or vice versa (i.e., the Seebeck effect). Harvesting electrical energy is also useful for cooling the various power-consuming and heat-retaining items that include electronic devices, automobiles, car seats, and cloth.

Traditional inorganic thermoelectric devices have garnered tremendous amounts of research due to their simple leg-type structure, high power density, and lack of noise pollution. However, only moderate improvements in conversion efficiency have resulted from this research. Typically, the resultant inorganic alloys contain heavy and expensive elements that require high processing temperatures and suffer from poor mechanical properties and toxicity issues. These issues have hindered the widespread use of the inorganic thermoelectric devices thus far.

Fully organic, electrically conductive composites may provide an environmentally friendly, light-weight alternative to the traditional inorganic thermoelectric devices. Polymer-based materials are of interest because of their intrinsically low thermal conductivity associated with their composite matrix (≦0.2 W/(m·K)). Polymer nanocomposites, composed of carbon nanotubes (“CNT”), may provide a suitable alternative to the traditional inorganic thermoelectric devices. Improvements are needed to the efficiency and effectiveness of these thermoelectric materials, as well as methods for synthesizing them.

Layer-by-layer deposition is a method of fabricating multilayer thin films that may be performed with a variety of materials and for a variety of substrate configurations. Layers of molecules are deposited sequentially onto a substrate through complementary molecular interactions, such as electrostatic or donor/acceptor attractions, to form alternating layers of materials. Deposition of a bilayer involves applying a first material, such as a polyelectrolyte or charge donor, to the surface of a substrate, rinsing the coated substrate, and repeating the application and rinse process for a second material, such as a polyelectrolyte having the opposite charge or a charge acceptor. Each layer is very thin and many layers may be deposited to achieve a particular property for the thin film. Thin films created by layer-by-layer deposition may be used on substrates as an oxygen barrier, flame retardant, or electrical conductor.

Thin films may be formed from thermoelectric materials for power generation or harvesting. Thermoelectric materials are materials capable of converting temperature differences to electric current. Typical thermoelectric materials include alloys, such as bismuth telluride and antimony telluride, and complex crystals, such as cobaltite oxides. Additionally, polymeric nanocomposites that exhibit a high power factor may be used as thermoelectric materials.

### SUMMARY OF THE INVENTION

The claimed invention relates generally to polymer composites having enhanced thermoelectric performance and methods for synthesizing the polymer composites. Some distinct features of this invention, compared to conventional inorganic thermoelectrics, include mechanical flexibility, easy processing, and the light-weight nature of the materials for fabricating thermoelectric devices. These make it possible to attach (or mount) thermoelectric devices made of the materials to any surfaces including human bodies, circular pipes, and the irregular geometric surfaces of many power consuming (or heat dissipating) devices. For instance, the thermoelectric materials can be used for powering small portable electronic devices such as smart watches, smart glasses, blue tooth devices, and wireless communication devices. Thermoelectric devices made of the invented materials can be used for actively cooling microprocessors.

In an embodiment of the invention, a layer-by-layer deposition process for a thermoelectric nanocomposite thin film having organic conducting polymers and organic conducting nanomaterials includes depositing a first polymer layer on a substrate, depositing a first nanomaterial layer on the first polymer layer, depositing a second polymer layer on the first nanomaterial layer, and depositing a second nanomaterial layer on the second polymer layer. The first polymer layer and the second polymer layer contain an organic conducting polymer. The first nanomaterial layer contains an organic, conducting two-dimensional (2D) nanomaterial. The second nanomaterial layers contain an organic, conducting one-dimensional (1D) nanomaterial.

### BRIEF DESCRIPTION OF THE DRAWINGS

The drawings included in the present application are incorporated into, and form part of, the specification. They illustrate embodiments of the present invention and, along with the description, serve to explain the principles of the invention. The drawings are only illustrative of embodiments of the invention and do not limit the invention.

FIGS. 1A to 1C shows the (A) electrical conductivity, (B) thermopower, and (C) power factor of CNT/PEDOT-Tos samples having varying CNT solution spraying times, in accordance with an embodiment of the claimed invention;

FIGS. 2A to 2C shows hole concentration and mobility results obtained by the Hall measurement method with (A) the same spraying time and different reduction levels; (B) different spraying times without reduction and (C) with reduction, in accordance with an embodiment of the claimed invention;

FIG. 3 shows a representation of an embodiment of the present composites made up of high mobility fillers in polymers;

FIGS. 4A to 4C show illustrations of (A) high mobility with quantum wells, (B) electronic band, and (C) the improved properties of the polymer composites;

FIGS. 5A and 5B shows the electrical properties, i.e., electrical conductivity and thermopower (A) and power factor (B) of PEDOT/CNT with different spray times of 20, 40, 60, 80 and 100 s, in accordance with an embodiment of the claimed invention;

FIGS. 6A and 6B shows the carrier mobility and carrier concentration of PEDOT/CNT before ( . . . . . . ) and after (—x—) TDAE treatment with different spray times of 20, 40, 60, 80 and 100 s, in accordance with an embodiment of the claimed invention;

FIG. 7 shows an exemplary flow chart depicting a method for synthesizing the thermoelectric material, in accordance with an embodiment of the claimed invention;

FIG. 8 is a diagram of a layer-by-layer deposition process to form an organic nanocomposite thin film, in accordance with an embodiment of the claimed invention;

FIG. 9 is an exemplary flow diagram of a process for creating an organic nanocomposite thin film from a conjugated conducting polymer, graphene, and multi-walled carbon nanotubes, in accordance with an embodiment of the claimed invention;

FIG. 10A is a graph of thickness of polyaniline (PANI)/graphene, PANI/double-walled carbon nanotubes (DWCNT), and PANI/graphene/PANI/DWCNT as a function of cycles; FIG. 10B is a graph of mass growth of PANI/graphene, PANI/DWCNT, and PANI/graphene/PANI/DWCNT as a function of cycles; FIG. 10C is a graph of sheet resistance of PANI/graphene, PANI/DWCNT, and PANI/graphene/PANI/DWCNT as a function of cycles; FIG. 10D is a graph of electrical conductivity of PANI/graphene, PANI/DWCNT, and PANI/graphene/PANI/DWCNT as a function of cycles; FIG. 10E is a graph of the Seebeck coefficient of PANI/graphene, PANI/DWCNT, and PANI/graphene/PANI/DWCNT as a function of cycles, according to embodiments of the disclosure; and FIG. 10F is a graph of the power factor of PANI/graphene, PANI/DWCNT, and PANI/graphene/PANI/DWCNT as a function of cycles, in accordance with an embodiment of the claimed invention;

FIGS. 11A to 11D show the characterization of electrical properties of samples before and after TDAE treatment;

FIGS. 12A to 12D show the environment-dependent electrical properties and thermal conductivity of the hybrid;

FIGS. 13A to 13C show the electrical properties of the hybrids vs. TDAE reduction time; and

FIGS. 14A and 14B shows ZT of Sample L along with Sample VL and M at different reduction times.

### DETAILED DESCRIPTION OF EXEMPLARY EMBODIMENTS

The present disclosure relates to polymer composites containing non-percolated networks of graphitic carbon that are useful as high performance thermoelectric energy harvesters and cooling devices.

In particular embodiments, conducting polymers are used to produce the polymer composites through the addition of graphitic carbon. Monomers are polymerized and then subjected to a de-doping process to maximize the power factor. High performance n- and p-type polymer composites can be obtained.

High performance of the composite results from the high electronic mobility channels embedded in the conducting polymers. The channels are created by unique electronic structures like quantum wells. The electronic charge carriers are attracted to the channels, and the carriers travel through the high mobility paths due to the energy barriers created by quantum wells. Graphitic carbons serve as high mobility channels. This makes it possible to reduce charge carrier concentrations so as to increase the Seebeck coefficient (or thermopower) without significantly sacrificing electrical conductivity.

In particular embodiments, conducting polymers such as poly(3,4-ethylenedioxythiophene) (PEDOT) or polyaniline are used to produce the composites through the addition of graphitic carbon such as CNT or graphene nanoribbons. Other conducting polymers that may be used in embodiments of the claimed invention include poly(acetylene)s (PAC), poly(p-phenylene vinylene)s (PPV), poly(pyrrole)s (PPY), polyanilines (PANI), poly(thiophene)s (PT), poly(p-phenylene)s (PPP), and poly(p-phenylene sulfide)s (PPS)

Monomers are polymerized with oxidants such as iron(III) tris-p-toluenesulphonate or iron chloride, and then undergoes a de-doping process such as vapor reactions with tetrakis(dimethylamino)ethylene for optimizing the carrier concentration in order to maximize the power factor (multiplication of a square of the Seebeck coefficient and electrical conductivity). The concentration of graphitic carbons such as carbon nanotubes is low enough to produce many non-percolated networks of graphitic carbons. For instance, most of the carbon nanotubes are not in direct contact, making high mobility conduits but low heat transport paths due to physically separated carbon nanotubes. Individual carbon nanotubes have very high thermal conductivity, however polymers have very low thermal conductivity. When carbon nanotubes are not well percolated, thermal transport becomes small due to the mismatch of vibration spectra (or phonon density of states). Nevertheless, electronic carriers can hop, resulting in finding the maximum points (maximum power factor). Upon a proper de-doping, a maximum power factor of p-type composites is obtained. When the polymer and graphitic carbons are fully de-doped, the composite becomes n-type.

An embodiment of the invention utilizes poly(3,4-ethylenedioxythiophene) (“PEDOT”) and carbon nanotubes (CNTs) to form polymer composites. Both p- and n-type composites have ZT higher than 1 at room temperature, indicating that thermoelectric performance is far superior to that of commercial inorganic semiconductor materials.

Some novel aspects of this disclosure is to avoid typical behaviors of electronic and thermal transport in bulk materials. A measure of the performance (or efficiency) of a thermoelectric material can be described by the thermoelectric figure of merit (often called Z or ZT, where T is temperature), which is defined as:

ZT=S²σT/(kₚₕₒₙₒₙ+k_{electron}) (1)

where S, σ, kₚₕₒₙₒₙ, and k_{electron} are the Seebeck coefficient (or thermopower), electrical conductivity, phononic (or lattice) thermal conductivity, and electronic thermal conductivity, respectively. Total thermal conductivity (k) is composed of phononic and electronic parts, i.e., k=kₚₕₒₙₒₙ+k_{electron}. In order to achieve a high ZT, it is required to obtain a large S²σ (called a power factor (PF)), but a small k. These three properties, however, are strongly correlated—changing one parameter favorably often makes the others undesirable. In typical bulks, an increase of carrier concentration for larger σ generally results in a decrease of S and an increase of k. This disclosure greatly improve thermoelectric performance by:
(1) decoupling S and a as to maximize the power factor; and
(2) suppressing the phononic thermal conductivity (kₚₕₒₙₒₙ) by properly designing the microstructures of the polymeric materials without significantly increasing the electronic thermal conductivity (k_{electron}).

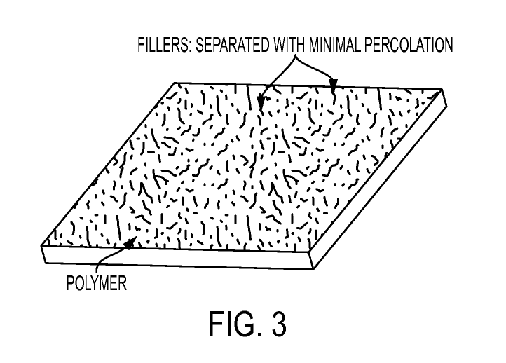

Embodiments of the invention are also directed to the methodology of synthesizing polymer composites in order to achieve the above characteristics. The essence of the polymer composites is to have materials with high electronic mobilities (also called “fillers”) embedded into polymeric materials in a non-percolated fashion. The fillers are positioned in a way that minimizes percolation, meaning that they are barely connected. See FIG. 3.

In essence, the Seebeck coefficient is largely increased while minimally sacrificing the electrical conductivity. Phononic thermal conductivity is kept low by minimizing the percolation of fillers that may have high thermal conductivity. Meanwhile, controlling carrier concentration in polymers makes it possible to control electronic properties of the composites.

A key aspect of the inventive compositions is based on improvement of electronic carrier mobility for polymeric materials whose electronic mobility is typically very low, compared to those of inorganic materials. The high electronic carrier mobility makes it possible to maintain moderate electrical conductivity even with low charge carrier concentrations. This allows for dramatically increasing the Seebeck coefficient by reducing the carrier concentration. The Seebeck coefficient is inversely proportional to the carrier concentration. In general, the low carrier concentration significantly reduces electrical conductivity in typical materials (an undesirable aspect), which is why it has been difficult to obtain excellent thermoelectric materials. Note that thermoelectric performance increases with both high electrical conductivity and Seebeck coefficient.

The mobility enhancement in the present polymer composites mainly comes from high electronic mobility conduits (fillers) embedded in conducting polymers. The following material characteristics are suitable for the conduits: (1) a mobility higher than that of polymers; (2) an electronic band gap smaller than that of the matrix material; and (3) an electronic band gap inside the band gap of the matrix material, which creates a quantum well structure.

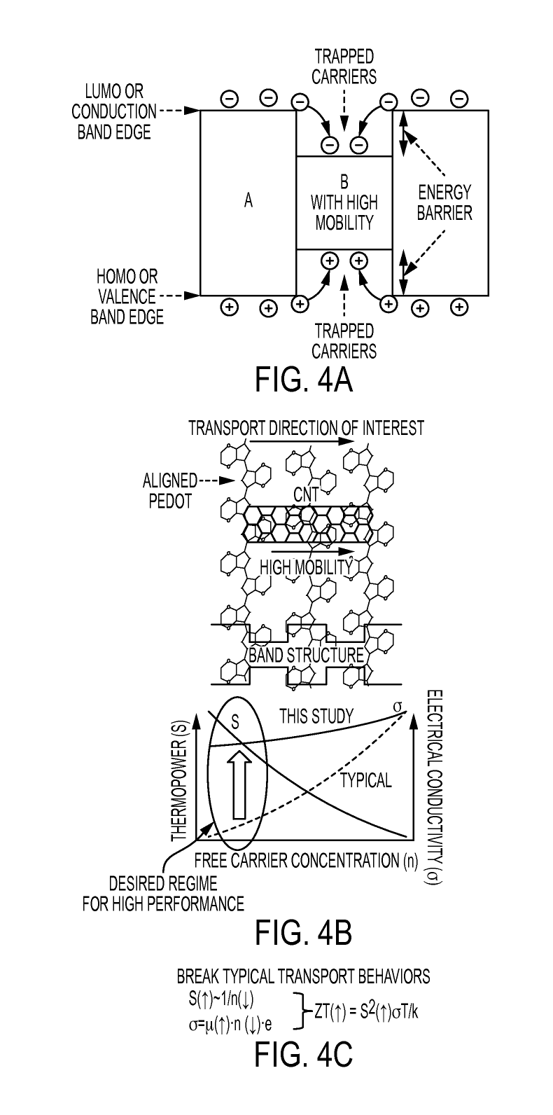

FIG. 4A shows that when a material (indicated as A) with a high mobility is used for interfacing another material (indicated as B) with a higher energy band location for electrons and holes, the energy barrier difference attracts electronic carriers (electrons or holes) to the smaller band gap material. With high mobility material B, it is possible to obtain a relatively high electrical conductivity with a low carrier concentration (n). For example, as shown in FIG. 4B, carbon nanotubes (CNTs) can be embedded into a conducting polymer to serve as high mobility conduits. FIG. 4C shows that thermopower (S) will be increased by lowering the carrier concentration (n). With the high mobility (μ) of carbon nanotubes, electrical conductivity (σ) can be significantly improved, as opposed to typical behaviors. This results in a large increase in the thermoelectric power factor (S²σ), resulting in a large thermoelectric figure of merit, ZT. In other embodiments, a material other than CNTs may be employed to serve as high mobility conduits. Indeed, any material that can be incorporated into a conducting polymer and through which electrons or holes can flow may be used in embodiments of the disclosure.

When the conduits are created by unique electronic structures such as quantum wells, the electronic charge carriers are attracted to the conduits, and the carriers travel through the high mobility paths due to the energy barriers created by quantum wells. Graphitic carbons including carbon nanotubes and graphene nanoribbons, which have very high electronic carrier mobilities and relatively small band gaps, are examplary materials that can serve as high mobility conduits. This makes it possible to reduce the charge carrier concentration of the composites so as to increase the Seebeck coefficient (or thermopower) without significantly sacrificing electrical conductivity. This unique features result in a high thermoelectric performance. The graphitic carbon such as carbon nanotubes has asymmetric electronic density of states, called van Hove singularities, which helps to increase the Seebeck coefficient upon optimizing the Fermi level via chemical doping and de-doping processes. Conducting polymers including poly(3,4-ethylenedioxythiophene) and polyaniline are exemplary matrix materials. Both p- and n-type materials can be made by controlling the Fermi level.

In certain embodiments, the polymer composites having enhanced thermoelectric properties are made up of a conducting polymer matrix and graphitic carbon filler. The graphitic carbon filler is dispersed throughout the conducting polymer matrix in a non-percolated fashion with minimal connections, and the polymer composites have a hole concentration that is reduced relative to the polymer matrix alone or the graphitic carbon filler alone and an electron mobility that is greater than that of the polymer matrix alone or the graphitic carbon filler alone. The conducting polymer matrix may be made of up poly(3,4-ethylenedioxythiophene), polyaniline, or mixtures thereof, or any suitable conducting polymer matrix material. The graphitic carbon filler may be carbon nanotubes (CNT), graphene nanoribbons, or mixtures thereof, or any suitable graphitic carbon material.

In other embodiments, the graphitic carbon fillers of the polymer composites have greater electronic mobility than the conducting polymer matrix, smaller electronic bandgap than the conducting polymer matrix, and an electronic bandgap that is inside a bandgap of the conducting polymer matrix. The polymer composites may comprise quantum wells and may have a reduced phononic thermal conductivity and an increased Seebeck coefficient (ZT). In other embodiments, the polymer composites may have a hole concentration of about 10¹⁸/cm³ and the polymer composites may have an electron mobility of about 14 cm²/Vs. The polymer composites may be p-type or n-type composites. P-type polymer composites may have a Seebeck coefficient (ZT) of about 5 at 300 K. N-type polymer composites may have a Seebeck coefficient (ZT) of about 2 at 300 K.

An exemplary method for synthesizing the polymer composites may include first combining a conducting polymer matrix material with graphitic carbon filler, then polymerizing the conducting polymer matrix material into a conducting polymer matrix that contains a concentration of graphitic carbon filler, and then optimizing the concentration of graphitic carbon filler by subjecting the conducting polymer matrix to vapor reduction using tetrakis (dimethylamino) ethylene (TDAE) to produce polymer composites. In certain embodiments, the graphitic carbon filler may first be sprayed on a substrate, then the conducting polymer matrix may be coated on the substrate in order to combine the two. In other embodiments, the step of polymerizing the conducting polymer matrix material comprises using iron(III) tris-p-toluenesulphonate, iron chloride, or mixtures thereof for oxidation.

In further embodiments, the step of optimizing the concentration of graphitic carbon filler may comprise subjecting the conducting polymer matrix to vapor reduction using tetrakis (dimethylamino) ethylene (TDAE) until a maximum thermoelectric power factor is reached to produce p-type polymer composites. In additional embodiments, the step of optimizing the concentration of graphitic carbon filler comprises subjecting the conducting polymer matrix to vapor reduction using tetrakis (dimethylamino) ethylene (TDAE) until a saturation point is reached to produce n-type polymer composites.

In additional embodiments, the n- and p-type polymer materials may be connected in series so as to produce thermoelectric devices. In order to increase the performance of power generation and cooling, the interface between the materials is an electrically conducting Ohmic contact, and multiple connections are used. The output voltage is increased as the modules are additionally connected.

The mechanical flexibility and light weight of the present polymer composites makes them unique and advantageous, compared to brittle and heavy commercial inorganic thermoelectric materials. Furthermore, the composites have low toxicity and are inexpensive compared to conventional inorganic thermoelectric materials containing toxic and expensive materials such as Te, Bi, Sb, and Pb. The polymer composites can be used to provide fabric like materials which can be designed for personal cooling and heating as well as energy harvesting from body heat. Their light weight makes them excellent for mobile devices and systems.

The polymer composites of the present disclosure can be used to produce high-performance thermoelectric energy harvesting and cooling devices and systems. Potential commercial applications include self-powered energy harvesting units operated by any type and grade heat including body heat and waste heat. The units can be connected to various sensors and electronic devices, which does not necessitate external power supply nor battery replacement. Furthermore, electronic devices including microprocessors used for computing can be actively cooled. The flexible and easily deformable polymer composites can be inserted between microprocessors and heat sinks, which can dramatically improve heat dissipation capability.

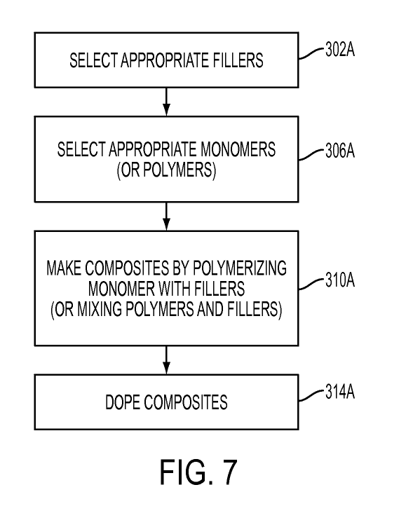

FIG. 7 is an example flowchart, depicting a method to synthesize a material with the disclosed thermoelectric effect. At 302A, appropriate fillers are selected. The filler material is chosen from any of a set of materials that possess any combination of the following characteristics: 1) an electronic mobility that is higher than the electronic mobility of the polymer matrix in which the filler material is embedded; 2) an electronic band gap that is smaller than the electronic band gap of the material in which the filler is embedded; and 3) an electronic band gap that is inside the band gap of the material in which the filler is embedded, creating a quantum well structure. At 306A, appropriate monomers or polymers are selected. The monomer is chosen from any organic materials that are capable of being conductors. At block 310A, the selected monomer is polymerized, using techniques known in the art for polymerizing the selected monomers with fillers to make composites. Alternatively, polymers are mixed with fillers to make composites. At block 314A, the composite is doped with the selected filler materials in a fashion such that the filler is non-percolated and is distributed within the polymer material.

Thermoelectric polymer nanocomposites may be formed through in situ techniques such as in situ polymerization and in situ deposition from emulsion. Conductive nanoparticles and conducting polymers may be dispersed in a bulk dispersion and the conducting polymer polymerized or deposited to form a thermoelectric nanocomposite with dispersed nanoparticles. Polymer nanocomposites may also be formed by layer-by-layer assembly. A substrate may be coated in a thin film by sequential deposition of two-dimensional layers of polymers and nanoparticles.

According to embodiments of the disclosure, an organic nanocomposite thin film with a high thermoelectric power factor may be formed through layer-by-layer assembly. A conductive polymer species and an organic conductive nanomaterial species may be sequentially and alternately deposited onto a substrate. The deposited organic conductive nanomaterial species may be alternated between a two-dimensional (2D) species, such as graphene nanoplatelets, and a one-dimensional species (1D), such as multi-walled carbon nanotubes (MWCNT), such that the resulting nanocomposite thin film contains a conjugated three-dimensional conducting network. This organic thin film may have increased electrical conductivity due to greater carrier mobility and the conjugated percolating network formed by the 1D nanomaterials, 2D nanomaterials, and conducting polymers. The thin film may be completely organic and applied through aqueous solutions.

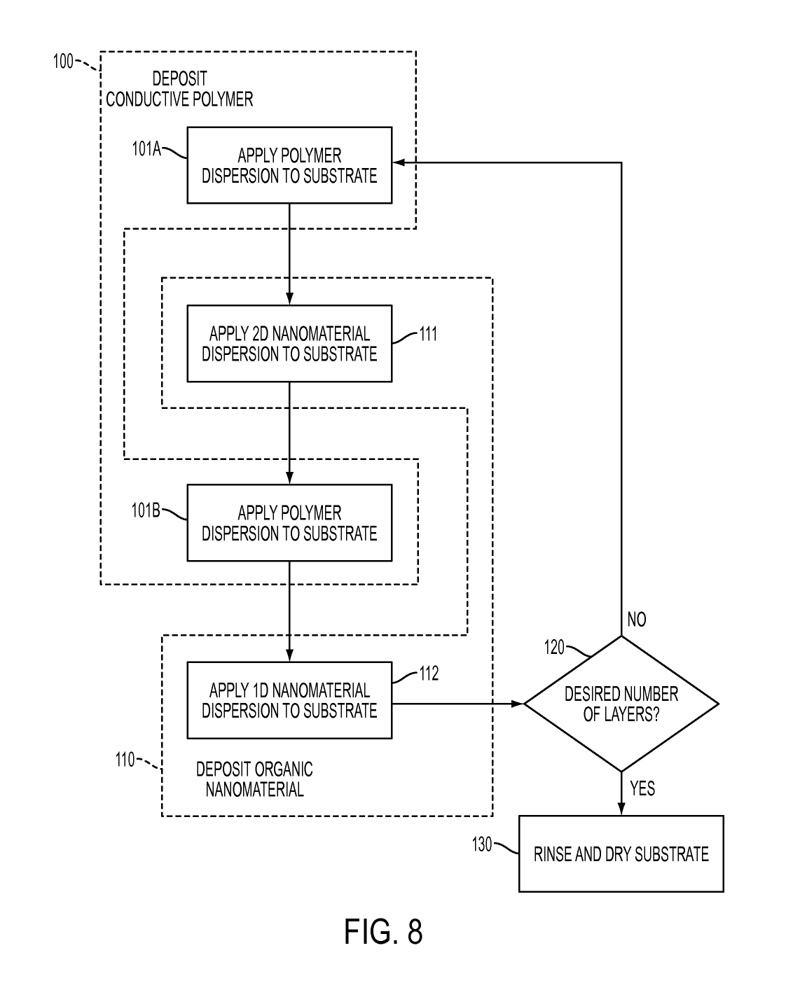

FIG. 8 is a diagram of a layer-by-layer deposition process to form an organic thermoelectric nanocomposite thin film on a substrate, according to embodiments of the disclosure. In FIG. 8, one or more quadlayers of (1) a conducting polymer, (2) a two-dimensional (2D) nanomaterial, (3) the conducting polymer, and (4) a one-dimensional (1D) nanomaterial are formed. However, different polymer and nanomaterial applications and sequences may be used to achieve different configurations. For example, a hexlayer of polymer/2D nanomaterial/polymer/1D nanomaterial/polymer/1D nanomaterial may be desired, and so two applications of 1D nanomaterials may be used for every application of 2D nanomaterials. While the word “layer” is used to indicate a sequential application of a species in layer-by-layer assembly, the actual nanocomposite thin film may not resemble layers due to adsorption or mobility of species during or after a deposition and absorption step.

Generally, a conducting polymer is deposited onto a substrate, as in 100, after which an organic conductive nanomaterial is deposited on the conducting polymer, as in 110. The organic conductive nanomaterial species may be alternated between 2D and 1D nanomaterials. This deposition process may be repeated until a thin film having the desired number of layers, applications, or properties is formed, as in 120, after which the substrate may be washed and dried, as in 130. More specifically, for the quadlayer deposition(s) of FIG. 8, a polymer dispersion may be applied to a substrate, as in 101A. Conducting polymers in the polymer dispersion may adsorb to the surface of the substrate, such as through electrostatic attraction, hydrogen bonding, or Van der Waals attraction. For example, a cationic conducting polyelectrolyte may adsorb onto a negatively charged substrate. The substrate may be rinsed to remove any unadsorbed polymers. For deposition and adsorption of a 2D nanomaterial on to the conducting polymer, a 2D nanomaterial dispersion may be applied to the polymer-coated substrate, as in 111, and the substrate may be rinsed. For deposition and adsorption of another conducting polymer layer, the polymer solution may be applied to the substrate, as in 10IB, and the substrate may be rinsed. For deposition and adsorption of a 1D nanomaterial on to the conducting polymer, a 1D nanomaterial dispersion may be applied to the substrate, as in 112, and the substrate may be rinsed.

Conducting polymers may be selected for their thermoelectric and deposition properties. A conducting polymer may be any organic intrinsically conducting polymer with at least one conjugated bond in the polymer backbone. Conducting polymer selection parameters may include polymer structure, conjugated nature and electron delocalization, thermal conductivity, electrical conductivity, thermoelectric figure of merit, molecular weight, polymer chain length, dopants, and molecular alignment. Conducting polymers that may be used include, but are not limited to, poly(acetylene)s (PAC), poly(p-phenylene vinylene)s (PPV), poly(pyrrole)s (PPY), polyanilines (PANI), poly(thiophene)s (PT), poly(3,4-ethylenedioxythiophene)s (PEDOT), polyaniline, poly(p-phenylene)s (PPP), and poly(p-phenylene sulfide)s (PPS).

The 2D and 1D organic nanomaterials may be selected for their electrical and deposition properties. An organic nanomaterial may be any organic, conducting material with at least one dimension in the nanoscale. A 2D nanomaterial may have one dimension in the nanoscale, while a 1D nanomaterial may have two dimensions in the nanoscale. Nanomaterial selection parameters may include electrical conductivity, surface charge, thermal conductivity, electron confinement and delocalization, functionalization, dopants, and mechanical strength. Organic 2D nanomaterials that may be used include, but are not limited to, graphene nanosheets, graphene nanoplatelets, expanded graphite sheets, and functionalized graphene nanostructures. Organic 1D nanomaterials that may be used include, but are not limited to, single-walled carbon nanotubes, double-walled carbon nanotubes, multi-walled carbon nanotubes, carbon nanotube ropes, polymer nanofibers, and functionalized carbon nanotubes.

The conducting polymer dispersion may be aqueous and may include stabilizers to aid in stabilization, solubility, and alignment of the conducting polymer. For example, a particular solvent may promote polymer-solvent interactions, which may reduce polymer entanglement and promote an expanded conformation to improve ordering of the conducting polymer during deposition. The 2D and 1D nanomaterial dispersions may be aqueous and may include stabilizers, such as stabilizing polymers or surfactants, to aid in exfoliation, deposition, and alignment of the nanomaterials. For example, a stabilizing polymer may be added to the nanomaterial dispersions to exfoliate the nanomaterials in suspension and uniformly disperse during deposition. Stabilizers that may be used for the conducting polymer, 2D nanomaterial, and 1D nanomaterial dispersions include, but are not limited to, poly(sodium 4-styrenesolfonate) (PSS), polyvinylpyrrolidone (PVP), poly(acrylic acid, sodium salt) (PAA), sodium dodecylbenzene sulfonate (SDBS), sodium dodecyl sulfate (SDS), lithium dodecyl sulfate (LDS), tetradecyl trimethyl ammonium bromide (TTAB), sodium cholate (SC), cetyltrimethyl ammoniumbromide (CTAB), sodium deoxycholate (DOC), and sodium taurodeoxycholate (TDOC).

This process may be adapted to current layer-by-layer deposition processes and used with a variety of substrates in a variety of conditions. A variety of layer-by-layer deposition techniques may be used, such as spray coating, spin coating, and immersion/dip coating. A variety of substrates may be used, such as fabrics, foams, PET films, silicon wafers, ABS sheets, and polymers.

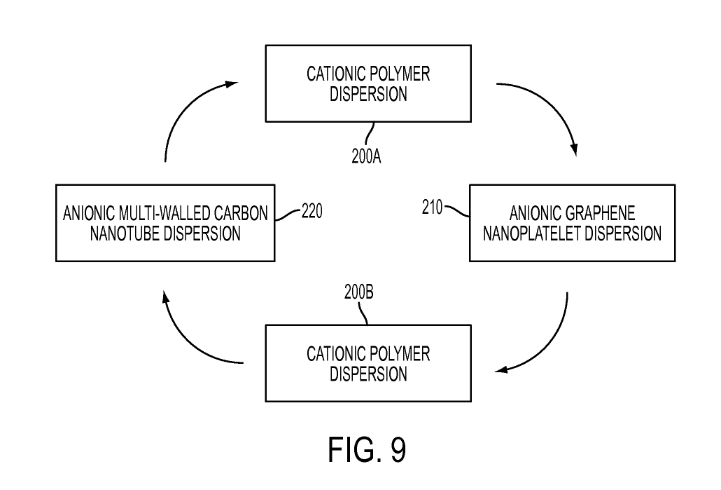

FIG. 9 is an exemplary flow diagram of a process for creating an organic nanocomposite thin film from a cationic conducting polymer, graphene nanoplatelets, and multi-walled carbon nanotubes, according to embodiments of the disclosure. In this example the conducting polymer dispersion is cationic and the nanoparticle dispersions are anionic; however, other charge configurations and components are possible.

A cationic polymer dispersion may be applied to a neutral or negatively-charged substrate, as in 200A. This cationic polymer dispersion may contain a cationic conducting polymer, such as polyaniline, and a solvent for aiding in solubility, such as N,N-dimethyl acetamide (DMAC). The positively-charged conducting polymer may adsorb to the surface of the substrate to form a conducting polymer layer. An anionic graphene nanoplatelet dispersion may be applied to the substrate, as in 210. This anionic graphene nanoplatelet dispersion may contain an anionic surfactant for dispersing the nanoplatelets in an aqueous dispersion and aiding deposition of the graphene nanoplatelets. The graphene nanoplatelets may adsorb to the positively-charged polymer on the substrate. The cationic polymer dispersion may be applied to the substrate, as in 200B. The positively-charged conducting polymer may adsorb to the I graphene layer to form a conducting polymer layer. An anionic multi-walled carbon nanotube (MWCNT) dispersion may be applied to the substrate, as in 220. The MWCNTs may adsorb to the conducting polymer layer.

The graphene, MWCNTs, and conducting polymer may form a conjugated 3D network. The interaction between the conducting polymer and the graphene and/or MWCNTs may promote electrical properties in the nanocomposite. Conjugated conducting polymers may adsorb and grow from the nanomaterials, forming a coating on the nanomaterials and creating a pathway for electron transport, which may increase the electrical conductivity and Seebeck coefficient. For example, PANI may grow around the MWCNTs in an expanded chain conformation, which may increase electron delocalization. This conducting polymer adsorption may be encouraged due to π-π interactions of the conjugated polymer and the nanomaterials. Additionally, the MWCNTs may act as bridges between the graphene layers, forming a more efficient and connected electrical percolating network.

This continuous three-dimensional network of polymer-wrapped MWCNT and graphene network may contribute to the thermoelectric properties of the nanocomposite. The conducting polymer, stabilized graphene, and stabilized MWCNTs may assemble into a uniformly structured network. The density of the interconnections between the conducting polymer and nanomaterials may increase as the number of layers increase.

### Working Examples

Poly(3,4-ethylenedioxythiophene)-tosylate (“PEDOT-Tos”) films were synthesized by a simple spin coating and reduction process. A few drops of prepared PEDOT-Tos solution were placed on the glass slide. The solution was spin coated at 2000 rpms, in order to have ˜75 nm of uniform thickness of the samples. The resulting samples were annealed at 110° C. for 5 min on a hot plate so as to polymerize the PEDOT-Tos film. After finishing polymerization, residual iron tosylates were removed by washing with deionized water. A few drops of tetrakis (dimethylamino) ethylene (TDAE) were placed in a closed chamber with PEDOT-Tos sample, and then a proper vacuum level was applied for TDAE vapor reduction. The reduction level can be controlled by different reduction time of the resulting PEDOT-Tos films.

In order to enhance the electrical conductivity without sacrificing thermopower, CNTs were added into the PEDOT-Tos film as conductive fillers. It was required to control the concentration of CNTs near percolation threshold because the electrical properties of the CNT/PEDOT-Tos film will follow those of CNTs when the CNTs form percolated networks in the matrix. In case of lower CNT concentration than its percolation threshold, it will be evenly distributed in the PEDOT-Tos matrix, constituting local conduits for carrier transport. The concentrations of the fillers were changed from 0.0005 wt % to little higher than its percolation threshold in order to optimize the power factor with high thermopower. Disconnected channels will filter lower energy carriers, resulting in higher thermopower from elevated average energy of total carriers.

First, the CNT network structure was investigated. The concentration of the CNTs was controlled by different spraying time and the network structures were inspected under scanning electron microscope (SEM) right after spraying. In order to verify the effect of the nanotube network, nanotubes were well dispersed in aqueous solution, and spraying process was precisely controlled. A denser nanotube network was achieved as the spray time was increased.

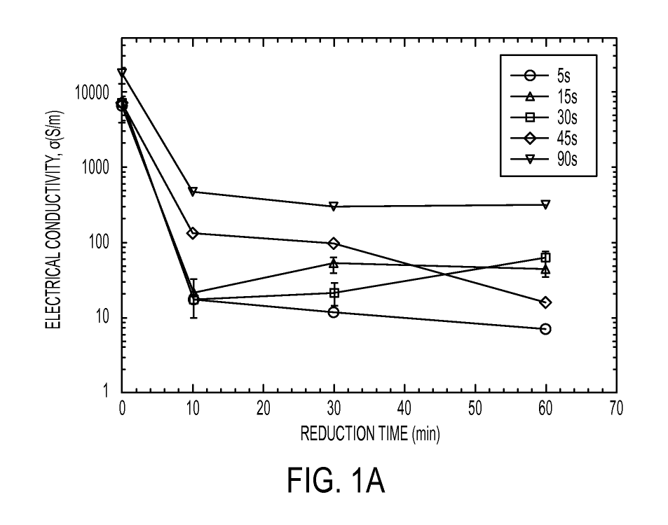

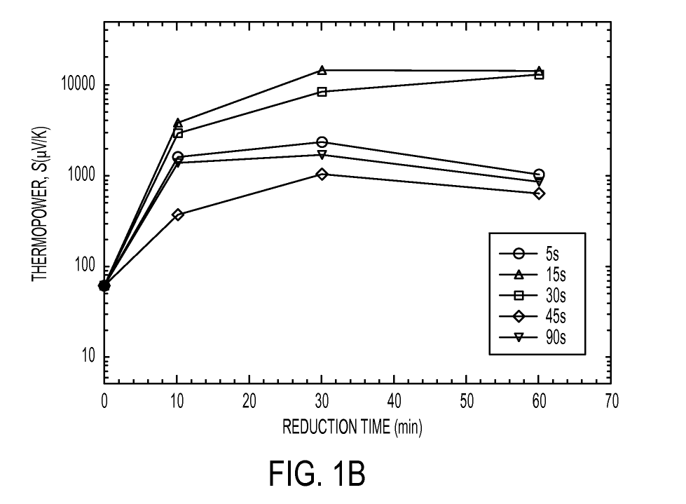

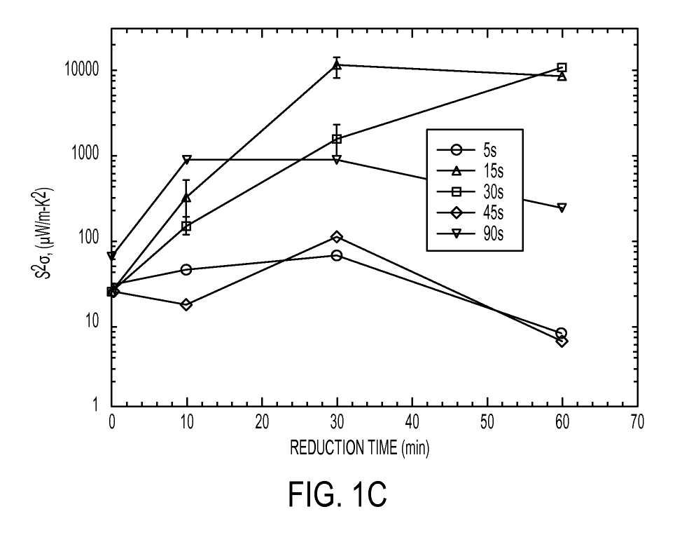

Thermoelectric behaviors were measured with a function of reduction time and the results are in FIGS. 1A to 1C. All conditions were fixed except for the CNT solution spraying time. The electrical conductivity of the CNT/PEDOT-Tos hybrids was ˜6,000 to ˜11,000 S/m without reduction. However, the electrical conductivity of all the samples was suddenly decreased even though the samples were exposed to tetrakis vapor only for 10 min (FIG. 1A). As increasing reduction time, noticeable changes were not found in electrical conductivity, which rather seems to be saturated at 30 min of exposure to tetrakis vapor. The conductivity of 45 sec and 90 sec spraying samples showed much higher values through whole range of reduction time since the major electron transport pathway was percolated nanotube networks rather than polymer matrix. In FIG. 1B, dramatic increase of thermopower was observed as increasing exposure time to tetrakis. Generally, the thermopower of each sample was increased by 30 min of reduction, and then saturated. The thermopower of the sets, rated from highest to lowest, were 15 sec, 30 sec, 5 sec, 90 sec and 45 sec. The maximum thermopower was obtained as ˜11 mV/K at 15 sec of spraying sample with 30 min of reduction. This is more than one order magnitude higher than any other reported values among organic thermoelectric materials. From this result, it would be explained that the nanotube network and reduction level are important factors to manipulate thermopower. The optimized nanotube concentration for thermopower was 15 sec, which was lower than percolation threshold. 30 sec of spraying sample also showed slightly lower thermopower (˜10 mV/K), but these values are much higher than that of 5 sec, 45 sec, or 90 sec spraying samples. FIG. 1C shows the power factor of CNT/PEDOT-Tos samples having varying CNT solution spraying times

To verify the electron doping effect as increasing reduction time, hole carrier concentration and mobility were measured by a home-made Hall test apparatus with the commonly used Van der Pauw method. Since the optimized results were obtained with 15 sec spraying samples, 0 to 60 min of reduced samples were prepared for the Hall test. Samples were coated on polycarbonate substrate, and cut into 1 cm by 1 cm square shapes. Silver paint was applied on the four corners of the sample, in order to make a better electrical contact between sample and electrodes. After mounting the sample, IT of magnetic field was applied with certain amount of current into the sample. Then, the hole carriers in the sample would move to one side by the Hall effect. From the migration of the carriers, induced Hall voltage was recorded by a Keithley multimeter as a function of time. At least 100 points were recorded and then averaged to get the Hall voltage for each configuration. By measuring sheet resistance and Hall voltages, the carrier concentration and mobility of each sample were possible to obtain.

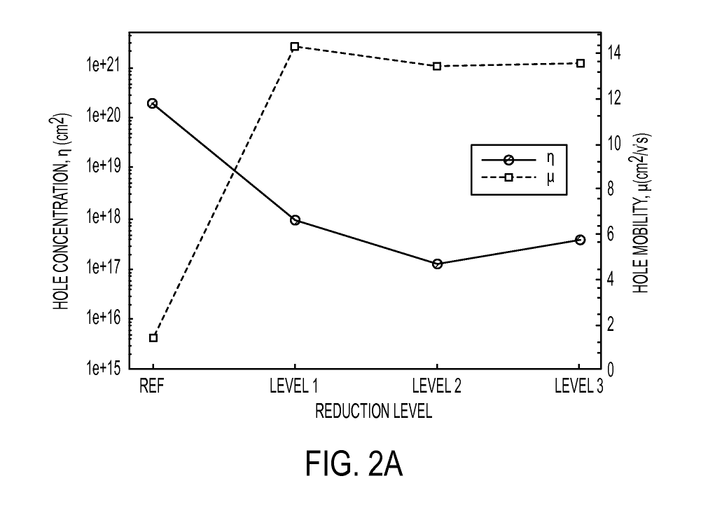

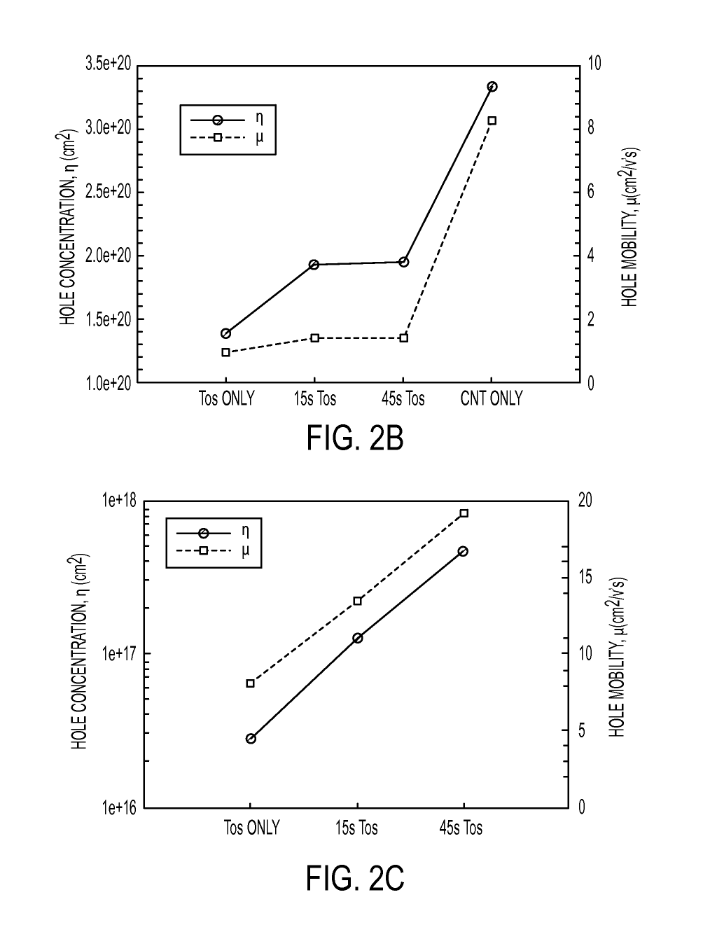

Hole concentration and mobility results obtained by the Hall measurement method are shown in FIGS. 2A to 2C with (A) the same spraying time and different reduction levels, and different spraying times (B) without reduction and (C) with reduction. Hole carrier concentration and mobility behavior of 15 sec sprayed samples as the reduction level changed are illustrated in FIG. 2A. Without reduction, the carrier concentration was around 10²¹/cm³, which was similar to typical conductive polymers. However, the concentration was suddenly dropped to 10¹⁸/cm³ after reduction, and then almost saturated for further reduction. This is direct evidence of electron doping of PEDOT, since the number of holes in the sample was reduced by heavy injection of electrons as reduction time increased. Hole mobility was initially ˜1 cm²/Vs, which was slightly higher than literature values for conductive polymers due to CNT networks in the polymer matrix. After reduction, the mobility was dramatically increased to ˜14 cm²/Vs, and saturated. Such kind of high mobility is the reason for the outstanding thermopower of the reduced samples.

Non-percolated CNT networks increased hole mobility by local pathways, and achieved elevated energy levels of carriers resulting high thermopower. The mobility results of the sample with different concentration of CNTs are depicted in FIGS. 2B and 2C respectively before and after reduction. A 100% CNT mat was also prepared with the spraying method, and then the carrier concentration and mobility were measured to compare the effect of CNTs in different concentration (PEDOT only, 15 sec, and 45 sec of sprayed samples). The mobility was increased with higher loadings of CNTs since the mobility of the CNT mat was much higher (8.26 cm²/Vs) than that of the PEDOT only sample (0.96 cm²/Vs). The hole concentration of the samples was increased when more and more CNTs were embedded as well.

In order to verify the electron doping effect on PEDOT, an electronic band diagram (the lowest unoccupied molecular orbital (LUMO), highest occupied molecular orbital (HOMO), and band gap) were experimentally obtained by cyclic voltammetry (CV) analysis for a 15 sec CNT sprayed PEDOT-Tos sample set (0 to 60 min of reduction). By using the cyclic voltammetry method, the oxidation and reduction potentials of the given materials could be obtained directly. When the potential of the electrode is lower than the HOMO of the sample, the electrons are depleted from sample to electrode (oxidation). On the other hand, reduction will occur when the electrode potential is higher than the LUMO level of the sample by electron addition to the sample. This phenomenon can be illustrated by current behavior with electrode potential variation.

N-type composites were synthesized as described below. The samples were prepared by spin-coating a solution containing n-Butanol (4 mL), Fe(III) chloride (330 mg), EDOT (142 mg) and pyridine (0.056 g) on CNT coated glass substrate at 2000 rpm for 30 s, respectively. The samples were heated up to 110° C. for 15 min and cooled down to room temperature slowly. After that, the samples were immersed in deionized water for half an hour to wash off inorganic salt and then dried in vacuum at 50° C. At last, the samples were treated with TDAE gas for 1 h and immediately transferred into vacuum at 50° C. for 2 h.

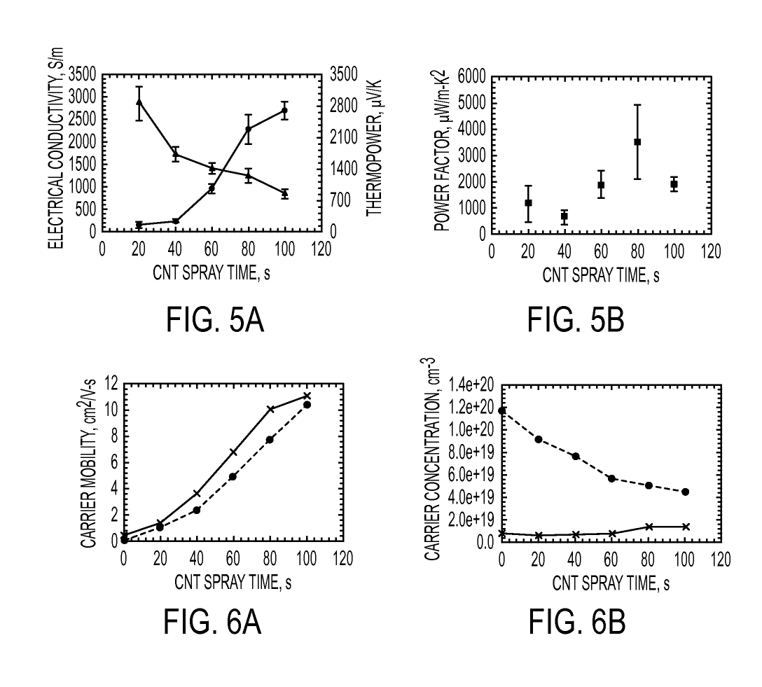

FIGS. 5A and 5B show the electrical properties of PEDOT/CNT nanocomposites having spray times of 20, 40, 60, 80 and 100 s after TDAE treatment for 1 hour. The electrical conductivity of PEDOT/CNT nanocomposites increases from 145±48 S/m to 2684±192 S/m when increasing the CNT spraying time from 20 s to 100 s. A high Seebeck coefficient, −2858±383 μV/K, was obtained at spraying time 20 s, which decreases fast with spraying time and reaches ˜842±109 μV/K at 100 s CNT spraying time. The highest power factor appears at 80 s CNT spraying time, which is 3502±1407 μW/m-K².

To determine the role of CNTs in the polymer nanocomposites, the carrier mobility and carrier concentration were measured. FIGS. 6A and 6B show the Carrier mobility and carrier concentration of PEDOT/CNT before ( . . . . . . ) and after (—x—) TDAE treatment with different spray times of 20, 40, 60, 80 and 100 s. As shown in FIGS. 6A and 6B, the intrinsic carrier mobility of PEDOT is as low as 0.03 cm²/V-s. While introducing CNTs into the polymer matrix, the mobility increases dramatically from 0.03 cm²/V-s to 1.07 cm²/V-s which is due to the intrinsic high electrical conductivity of carbon nanotubes. As the CNT spraying time increases, the carrier mobility keeps increasing and reaches 10.4 cm²/V-s at the spraying time of 100 s. After TDAE treatment, the carrier mobility of polymer only samples increases to 0.5 cm²/V-s, which might be due to the better alignment of the polymer chain. Although the alignment of polymer leads to obvious enhancement for mobility of polymer only samples, the value of carrier mobility for polymer/CNT nanocomposite increases slightly since the value of carrier mobility is dominated by CNT. The carrier concentration of polymer nanocomposites decreases while raising the CNT spraying time before treatment. After being treated by TDAE, the composites' carrier concentration decreases by an order because of the low n-type doping.

To understand the effect of TDAE on CNTs, a CNT only sample with 40 s spraying time and CNT films on polytetrafluoroethylene (PTFE) membrane were prepared. Before TDAE treatment, both of the 40 s CNT only sample and CNT films show p-type properties which have Seebeck coefficient values of 18 μV/K and 56 μV/K, respectively. The lower Seebeck coefficient value of CNT only sample should be attributed to the gaps existing in the CNT disconnected networks which blocks the charge carrier. The gaps are also the main reason resulting in the low electrical conductivity of 40 s CNT only sample which is only ˜80 s/m. CNT films show a typical Seebeck coefficient value of −56 μV/K which is consistent with the previously reported result. After TDAE treatment, both of the 40 s CNT only samples and CNT films show n-type properties which have Seebeck values of −40 μV/K and −46 μV/K, respectively as shown in Table 1 below.

TABLE 1

| | | Thin CNT film on glass | Thick CNT film, |
|---|---|---|---|
| | | substrate, | Filtrated CNT |
| | | Spraying time 40 s | networks |
| Seebeck | Before TDAE | 18 μV/K | 56 μV/K |
| coefficient | treatment | | |
| | After TDAE | −40 μV/K | −46 μV/K |
| | treatment | | |

Considering the method by which the polymer+CNT composite is made, an equivalent 2D model utilizing planar connections of resistors was employed for calculating the thermal conductivity of the composite. In order to have a model which has a similar geometry with the fabricated samples (having 15 seconds of spraying time), the averaged length, diameter, and number of CNTs were obtained from 5 SEM images. As a result of the observation, the average length L=1.5 um, diameter D=40 nm, and volume fraction of CNT V_{CNT}=0.163% were decided to be input parameters. Although the curvature of an individual CNT affects the thermal conductivity for composites of high CNT concentration, the low-CNT-concentration composites have negligible impacts from curvature. Therefore the shape of CNT was assumed to be straight in this model for simplicity.

It is crucial to note that k is dependent on the width of matrix even though V_{CNT}=0.163% is fixed. k increases as the width of the matrix increases, assuming k_{CNT}=1000 W/mK and k_{polymer}=0.3 μW/mK tentatively. The width was determined based on electrical conductivity data. Table 2 shows the electrical conductivity of CNT+polymer sample and polymer only sample. As shown in Table 2, σ_{polymer,}=3.63 S/m and ^{σ}_{polymer}+_{CNT}=52.5 S/m, assuming ^{σ}_{CNT}=70,000 S/m. The next step is to back-calculate the matrix width using ^{σ}_{polymer}+_{CNT}=52.5 S/m. When a matrix width of 62.5 μm was used, ^{σ}_{polymer}+_{CNT}=˜52.5 was obtained.

TABLE 2

| | Electrical |
|---|---|
| Sample | conductivity (S/m) |
| PEDOT + Tos matrix with 30 min reduction | 3.63 |
| CNT + PEDOT + Tos matrix with 30 min reduction | 52.25 |

The thermal conductivity of CNT+Polymer matrix of 15 second spraying time was calculated with k_{Polymer}=0.3 W/mK and k_{CNT}=200 (effective thermal conductivity of CNT containing the junction effect), 300, 500, 800, and 1000 W/m-K as the upper bound (which corresponds to the lower bound of ZT). When k_{CNT}=200 W/mK, k is 0.55 W/mK and the upper bound is expected to be k=1.29 W/mK (when k_{CNT}=1000 W/mK).

Considering the thermal conductivity of a CNT mat is ˜200 W/m-K, the thermal conductivity of the composites is expected to be as low as ˜0.6 W/m-K. Therefore, ZT values for the p-type composites are as high as 5 at 300 K and ZT values for the n-type composites are as high as 2 at 300 K.

PANI/graphene and PANI/DWCNT films were synthesized as described below. 0.05 wt % graphene nanoplatelets (micron diameter; nanometer thickness) was dispersed in deionized (DI) water containing 0.02 wt % poly(4-styrenesulfonic acid) (PSS) to create an anionic graphene aqueous dispersion. 0.05 wt % double-walled carbon nanotubes (DWCNT; micron length; nanometer diameter) was dispersed in DI water containing 0.25 wt % sodium dodecyl benzene sulphonate (SDBS) to create an anionic DWCNT aqueous dispersion. The anionic graphene and DWCNT dispersions were sonicated and centrifuged. 0.1 g polyaniline (PANI) was dissolved in 30 g of N,N-dimethyl acetamide (DMAC) to form a cationic PANI solution. The PANI solution was sonicated and adjusted to pH 2.5 with pH 3.0 water.

PANI/graphene and PANI/DWCNT films were fabricated by sequential deposition/adsorption of the cationic PANI and the anionic graphene or DWCNT for 5 min, followed by DI water rinsing for one min between each adsorption step. After assembling the first bilayer of each film, the deposition/adsorption time for each subsequent layer was 1 min. PANI/graphene/PANI/DWCNT films were fabricated by sequential deposition/adsorption of the cationic PANI and alternating anionic graphene and DWCNT, beginning with sequential adsorption of the cationic PANI and anionic graphene for 5 min, followed by DI water rinsing for one min between each adsorption step. After assembling the first PANI/graphene bilayer, the deposition/adsorption time for each subsequent layer was 1 min. Each nanocomposite thin film was deposited on a silicon wafer substrate.

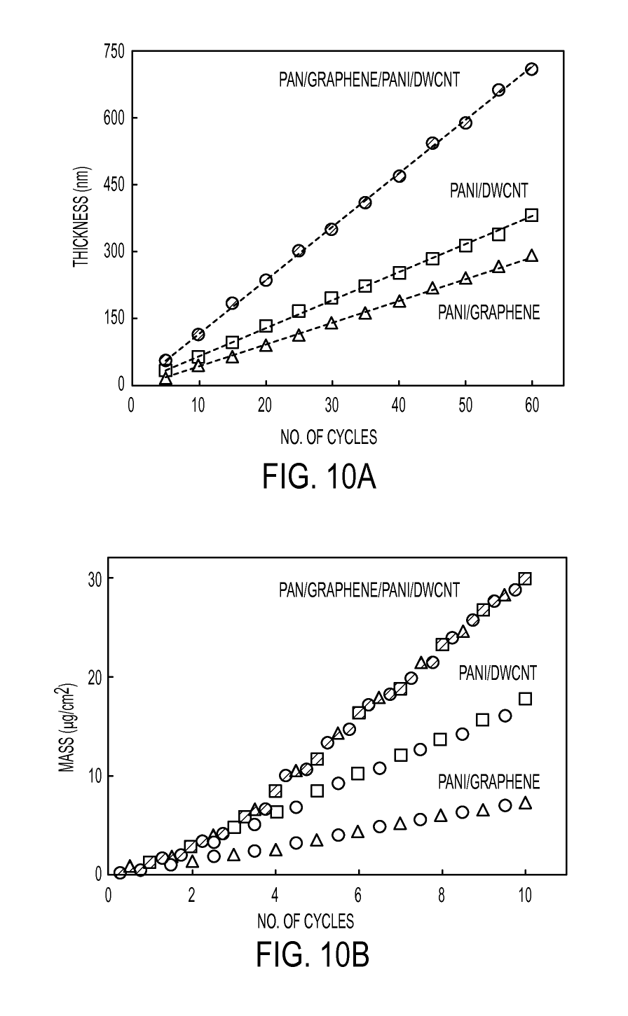

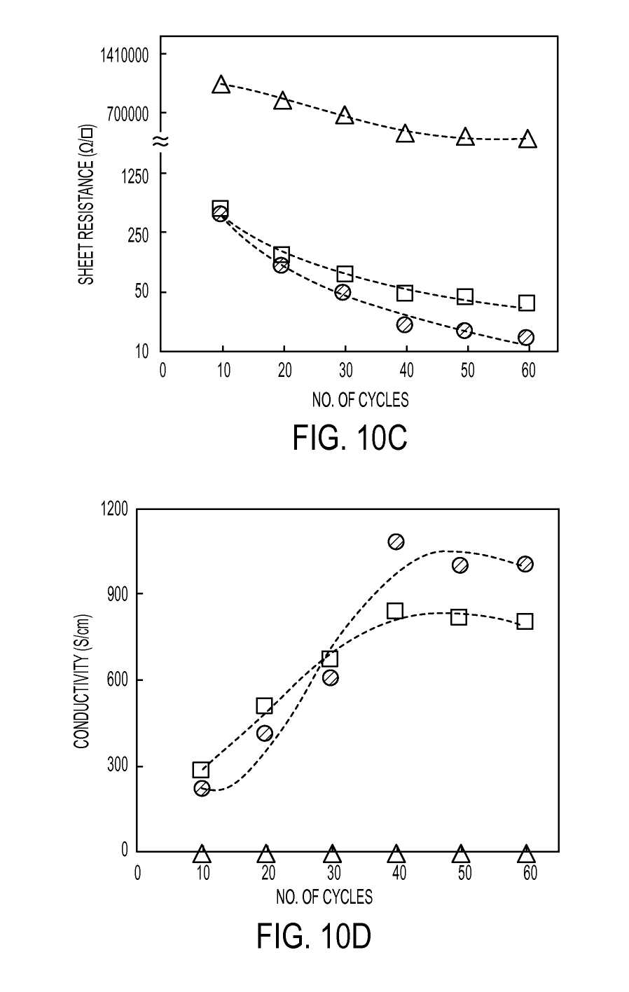

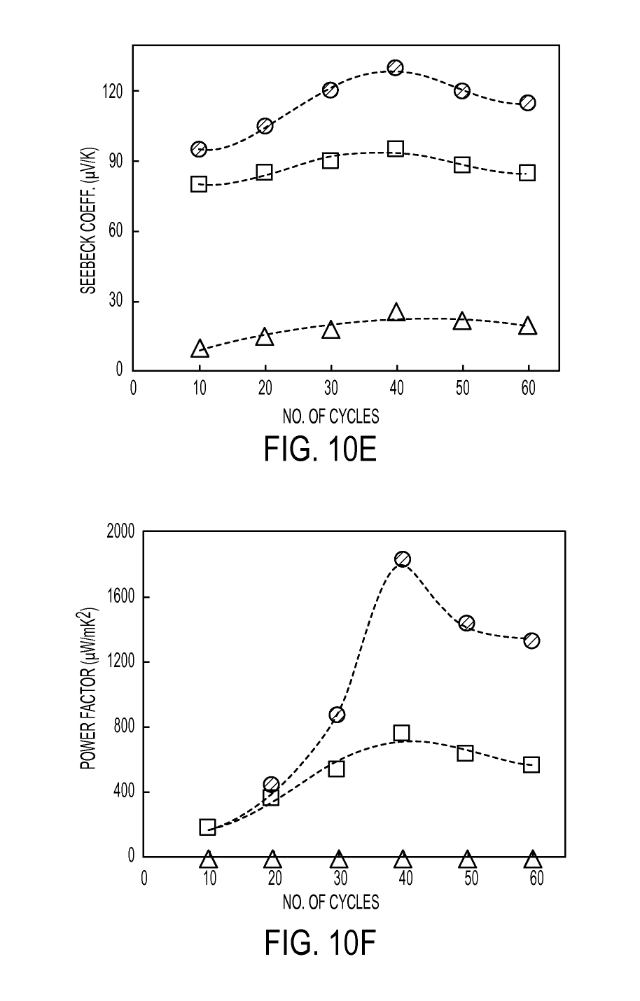

FIG. 10A is a graph of thickness of PANI/graphene, PANI/DWCNT, and PANI/graphene/PANI/DWCNT as a function of cycles, according to embodiments of the disclosure. The thickness of the quadlayer is close to the sum of the DWCNT and graphene bilayers, suggesting uniform and well-controlled assembly. FIG. 10B is a graph of mass growth of PANI/graphene, PANI/DWCNT, and PANI/graphene/PANI/DWCNT as a function of cycles, according to embodiments of the disclosure. Mass deposition for the quadlayer film is approximately linear, suggesting constant composition during assembly.

FIG. 10C is a graph of sheet resistance of PANI/graphene (open triangle), PANI/DWCNT (open square), and PANI/graphene/PANI/DWCNT (closed circle) as a function of cycles, according to embodiments of the disclosure. The sheet resistance decreased with increasing layer deposition, suggesting a more continuous three-dimensional network and a more efficient electron transport pathway. FIG. 10D is a graph of electrical conductivity of PANI/graphene (open triangle), PANI/DWCNT (open square), and PANI/graphene/PANI/DWCNT (closed circle) as a function of cycles, according to embodiments of the disclosure. The higher conductivity of carbon nanotube films suggest a more efficient percolating network compared to graphene platelets. The quadlayer conductivity increased with increasing layers, suggesting increased connectivity of the graphene and DWCNT network.

FIG. 10E is a graph of the Seebeck coefficient of PANI/graphene, PANI/DWCNT, and PANI/graphene/PANI/DWCNT as a function of cycles, according to embodiments of the disclosure. The quadlayer film exhibited a Seebeck coefficient of 130 μV/K at 40 QL. FIG. 10F is a graph of the power factor of PANI/graphene, PANI/DWCNT, and PANI/graphene/PANI/DWCNT as a function of cycles, according to embodiments of the disclosure. The quadlayer film exhibited a power factor of 1825 μW/(m-K²) at 40 QL.

Hybrids of carbon nanotubes (CNTs) and poly(3,4-ethylenedioxythiophene) (PEDOT) treated by tetrakis(dimethylamino)ethylene (TDAE) have large n-type voltages in response to temperature differences, resulting in high power factors, ˜1050 μW/m-K². Large thermopower could be attributed to greatly reduced electron concentrations but partially-percolated but high electron mobility CNT networks minimally reduced electrical conductivity. With a low thermal conductivity, ˜0.67 W/m-K due to thermally resistive CNT junctions intervened by PEDOT via in-situ polymerization, a large figure-of-merit, ˜0.5 at room temperature was obtained. The presented methodology could be adopted for developing new hybrids and composites with desired electronic and thermal transport properties beyond thermoelectrics.

CNT preparation: 2-mg of single-wall CNTs (P2 grade, carbonaceous purity >90%, metal contents of 4-8 wt %, Carbon Solutions, Inc.) was sonicated in 20-ml of deionized (DI) water with 10-mg of sodium dodecyl benzene sulfonate (SDBS) (88%, Acros organics) for 6 hr in an ultrasonic bath (Branson 1510) and then 1-hr with a pen-type sonicator (Misonix Microson XL2000, 10 W). The obtained CNT solution was centrifuged for 20 min at 12000 rpm (accuSpin Micro17, Fisher Scientific). The supernatant was used for spraying the solution on glass substrates at ˜80° C. for different time periods with a spray gun (0.2-mm nozzle diameter, GP-S1, Fuso Seiki Co.). The CNT-sprayed substrate was immersed into deionized (DI) water for 30 min to wash off SDBS and then fully dried in a vacuum oven (˜0.1 Torr) at 50° C. typically for ˜20 min. To prepare CNT-only, the CNT solution was sprayed on glass substrates for ˜200 sec (unless specified), which resulted in ˜100 nm in thickness.

Polymerization: A solution was prepared by dissolving 330-mg FeCl₃ (anhydrous, 98%, Alfa Aesar) in 4-mL n-Butanol. Then, 56-mg pyridine (99+%, Alfa Aesar) was added to the solution. A monomer solution was made by adding 142-mg of 3,4-ethylenedioxythiophene (EDOT) (98+%, TCI) to the mixture. After the solution was sonicated for 15 min in the ultrasonic bath, the solution was spin-coated on CNT-coated glass substrates at 2000 rpm for 30 sec. The substrate was kept at 110° C. in an oven for 15 min and cooled down to room temperature slowly at a rate of approximately 1° C./min, and then immersed into DI water for 30 min to wash off inorganic salts and then dried in the vacuum oven at 50° C. PEDOT-only samples were prepared with the same procedures on glass substrates without CNTs. Typical film thickness was measured to be 120±20 nm.

TDAE treatment: A few drops of TDAE (85+%, Sigma Aldrich) were added to the bottom of a box, and the prepared sample was attached to the lid of the box. Then the box was placed in a vacuum chamber (68-70 kPa) with 30% of relative humidity for 1 hr at room temperature. The reduced sample was annealed in the vacuum oven at 50° C. for 30 min. Typical film thickness after TDAE treatment was measured to be 214±30 nm.

Sample preparation and testing in the “inert”, “air”, and “humid” environment: For the inert sample, TDAE treatment was carried out in an Ar glove box (O₂<1 ppm and H₂O<0.1 ppm), and electrical properties were measured in an air-tight setup filled with Ar. For the air sample, the annealing process was omitted after TDAE treatment, and electrical properties were measured in ambient conditions (relative humidity: typically 35-40% but swings from 25% to 65%; temperature: 21-22° C.). For the humid sample, the annealing process was also omitted after TDAE treatment. The sample and a wet paper were transferred to the air-tight setup filled with argon, and electrical properties were measured after 30 min in order to saturate the environment with H₂O.

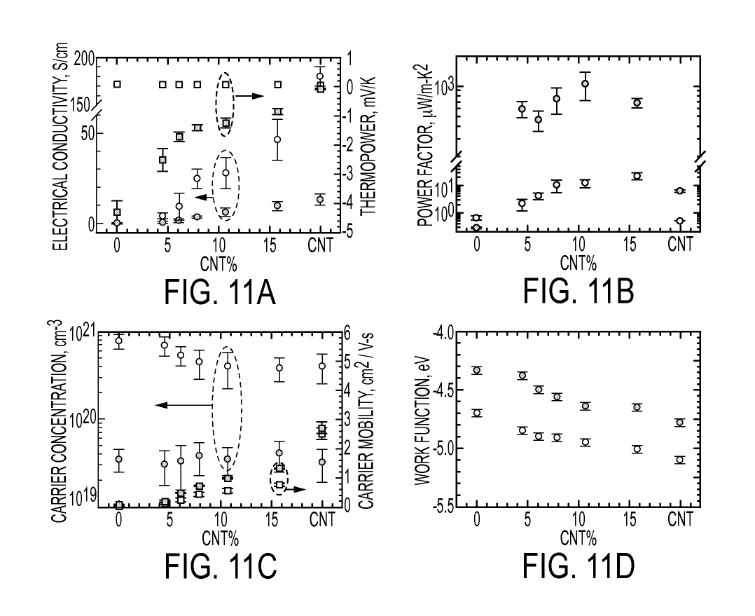

FIGS. 11A to 11D show the characterization of electrical properties of the samples before and after TDAE treatment. Electrical conductivity and thermopower (A), power factor (B), Majority carrier concentration and mobility (C), and work function (D) of CNT/PEDOT hybrids with 4.5%, 6.1%, 7.9%, 10.7%, and 15.8% (respectively corresponding to 20-s, 40-s, 60-s, 80-s, and 100-s CNT spray) CNT coverage percentage. PEDOT-only, and CNT-only samples before TDAE treatment (hollow symbols) and after TDAE treatment (filled symbols) are also shown.

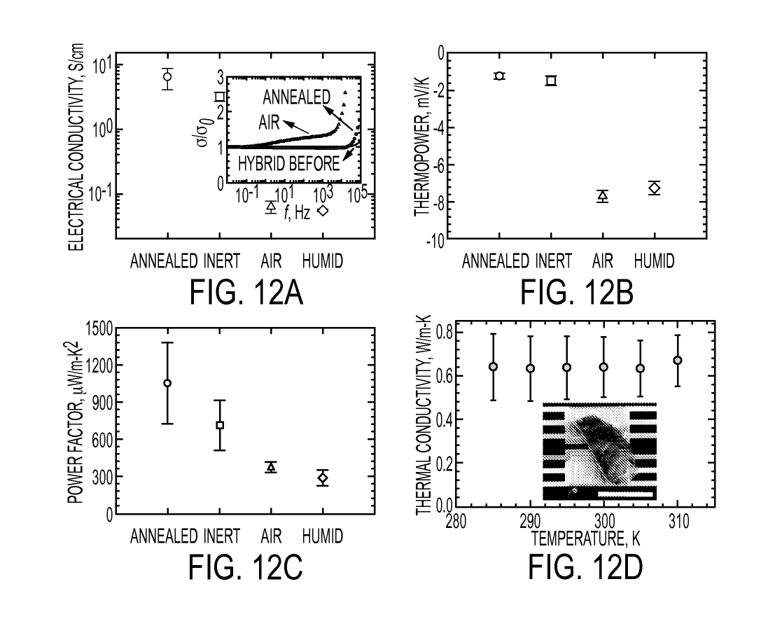

FIGS. 12A to 12D show the environment-dependent electrical properties and thermal conductivity of the hybrid. A-C, Electrical conductivity, thermopower, and power factor when the hybrids were annealed after TDAE treatment and measured in air (“annealed”; typical sample preparation method in this study); when measurement were carried out in Ar (“inert”), air (“air”), H₂O-saturated Ar (“humid”) environment. TDAE treatment was performed in Ar environment for all samples. The inset in “A” shows AC electrical conductivity normalized by those at a low frequency. FIG. 12D shows thermal conductivity of the hybrid near room temperature. A representative SEM of the hybrid bridged between two suspended membranes in a microdevice is shown in FIG. 12D. The scale bar indicates 30 μm.

Hybrids of poly(3,4-ethylenedioxythiophene)-tosylate (PEDOT-Tos) and carbon nanotubes (CNTs) have large ZTs, up to 1.4 at 300 K, which is even superior to those of inorganic counterparts. We believe this large increase comes from a large thermopower with decent electrical conductivity mainly due to two reasons: (1) the reduction of carrier concentration and (2) high electronic mobility enabled by quantum well structures. Meanwhile well-separated CNTs created CNT junctions intervened by PEDOT-Tos, suppressing thermal transport. Our new methodology of creating high electronic mobility conduits allowed for reducing the electronic carrier concentration so as to yield a remarkable increase in thermopower without significantly sacrificing electrical conductivity. We anticipate that the high ZT materials open up new fields of flexible TE energy harvesting and cooling, and this methodology can be adopted for developing new hybrids and composites with desired electronic and thermal transport properties beyond thermoelectrics.

The CNT solutions were prepared by dispersing 2-mg of singe-wall CNTs (P2 grade, carbonaceous purity >90%, metal contents of 4-8 wt %, Carbon Solutions, Inc.) in 20-mL of deionized (DI) water with 6-mg of sodium dodecyl benzene sulfonate (SDBS) (88%, Acros organics) with a bath type sonicator (Branson 1510) for 2 hours and then a probe sonicator (48 W, Fisher Scientific FB 120) for 2 hours. This process was repeated three times, and then the solution was centrifuged at 12,000 rpm for 20 minutes (Fisher Scientific accuSpin Micro17). The upper ˜70% of the supernatant solution was carefully decanted and directly sprayed with a spray gun (0.2 mm nozzle diameter, GP-S1, Fuso Seiki Co.) onto glass substrates at ˜80° C. for varying time periods. Subsequently, the samples were immersed in DI water for 10 minutes to remove SDBS and then the water was blow-dried by air in ambient conditions. The monomer solution was prepared by adding 126-mg of EDOT (98+%, TCI) to an oxidative solution containing 2.03-g of iron (III) tris-p-toluenesulphonate in n-butanol (38-42 wt %, Clevios C-B 40 V2), 2.03-g of n-butanol (99.4%, EMD), and 56-mg of pyridine (99+%, Alfa Aesar). 0.24-mL of this solution was spin-coated on the CNT-sprayed glass substrates at 2000 rpm for 30 seconds. Subsequently, the samples were placed in a convection oven at 110° C. for 10 minutes for polymerization, and then naturally cooled down to room temperature (˜30 minutes). Finally, the samples were immersed in DI water to remove excessive iron tosylate for 10 minutes and blow-dried by air. The film thickness was measured to be 80-110 nm by using a surface profilometer (KLA-Tencor P-6). For the reduction process, a few drops of tetrakis (dimethylamino) ethylene (TDAE) (85%, Sigma Aldrich) were widely spread on the bottom of a box, and the prepared sample was attached to the lid of the box so as to expose the sample to the TDAE vapor. The reduction process was performed in a vacuum environment (68-70 kPa) with 30% of relative humidity at room temperature. The reduction level was controlled by varying the TDAE exposure time. The PEDOT-Tos only sample was prepared by spin-coating 0.24-mL of monomer solution on a glass substrate at 2000 rpm for 30 seconds. Subsequently, the samples were placed in a convection oven at 110° C. for 10 minutes for polymerization. The sample thickness was measured to be 105 nm. The CNT only sample was prepared by spraying the CNT supernatant solution on a glass substrate at ˜80° C. with the spray gun for 200 sec. The sample thickness was measured to be 40 nm.

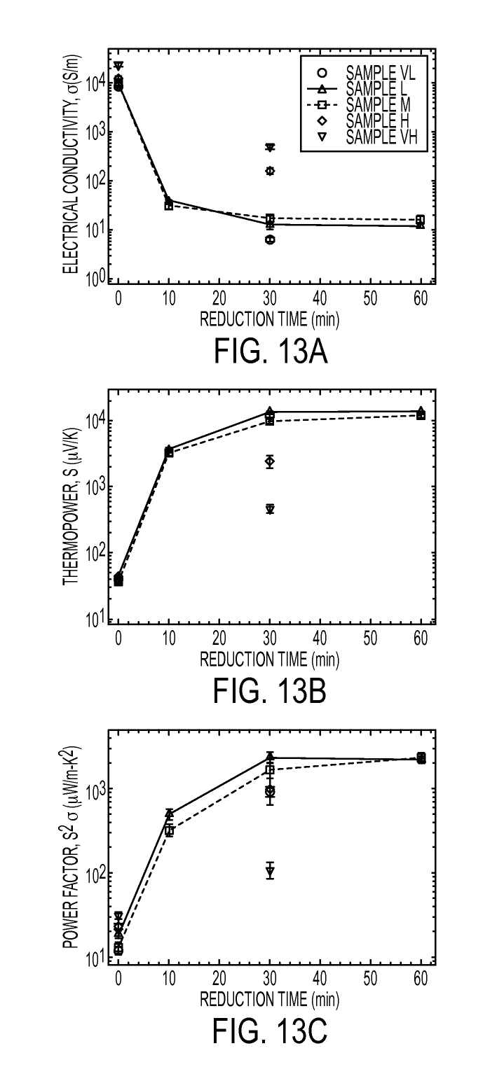

FIGS. 13A to 13C show the electrical properties of the hybrids vs. TDAE reduction time. FIGS. 13 A-C show the electrical conductivity, thermopower, and TE power factor of Sample L and M after TDAE reduction for 10, 30, and 60 min; and those of Sample VL, H, and VH after 30-min reduction. The reduction effect was saturated after exposing the samples to the TDAE vapor for 30 min.

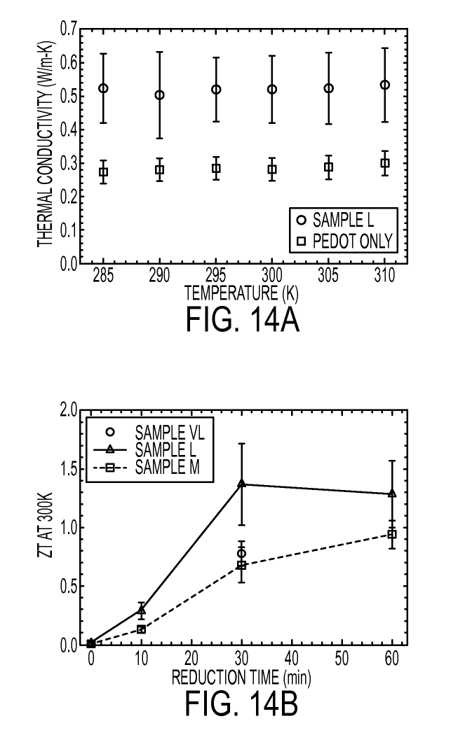

FIGS. 14A and 14B shows ZT of Sample L along with Sample VL and M at different reduction times. The maximum ZT at 300 K from Sample L was found to be 1.4, which is the highest among organic materials as well as better than that of commercial Bi—Te alloys (ZT˜0.8 at 300K). It should be noted that the thermal conductivity of Sample L was not strongly affected by the reduction time due to the small electronic contribution. The thermal conductivity values of Sample L before and after the reduction were similar. The ZT values of Sample VL and M were also calculated by using their thermal conductivities obtained from the Monte Carlo calculations with the thermal conductivity of CNTs (60 W/m-K) as an input parameter.

Although the present invention has been described in terms of specific embodiments, it is anticipated that alterations and modifications thereof will become apparent to those skilled in the art. Therefore, it is intended that the following claims be interpreted as covering all such alterations and modifications as fall within the true spirit and scope of the invention.

What is claimed is:

1. A polymer composite having enhanced thermoelectric properties, comprising:
a conducting polymer matrix; and
a graphitic carbon filler, wherein the graphitic carbon filler is dispersed throughout the conducting polymer matrix in a non-percolated fashion with minimal connections, and wherein the polymer composite has a hole concentration that is reduced relative to the conducting polymer matrix alone or the graphitic carbon filler alone and an electron mobility that is greater than that of the conducting polymer matrix alone or the graphitic carbon filler alone.

2. The polymer composite of claim 1, wherein the conducting polymer matrix is comprised of poly(3,4-ethylenedioxythiophene), polyaniline, or mixtures thereof.

3. The polymer composite of claim 1, wherein the graphitic carbon filler is carbon nanotubes, graphene nanoribbons, or mixtures thereof.

4. The polymer composite of claim 1, wherein the polymer composite has reduced phononic thermal conductivity and an increased Seebeck coefficient (ZT).

5. The polymer composite of claim 1, wherein the graphitic carbon fillers have greater electronic mobility than the conducting polymer matrix, smaller electronic bandgap than the conducting polymer matrix, and an electronic bandgap that is inside a bandgap of the conducting polymer matrix.

6. The polymer composite of claim 1, wherein the polymer composite comprise quantum wells.

7. The polymer composite of claim 1, wherein the hole concentration of the polymer composite is about 10¹⁸/cm³.

8. The polymer composite of claim 1, wherein the electron mobility of the polymer composite is about 14 cm²/Vs.

9. The polymer composite of claim 1, wherein the polymer composite is a p-type composite.

10. The polymer composite of claim 9, wherein the polymer composite has a Seebeck coefficient (ZT) of about 5 at 300 K.

11. The polymer composite of claim 1, wherein the polymer composite is an n-type composite.

12. The polymer composite of claim 11, wherein the polymer composite has a Seebeck coefficient (ZT) of about 2 at 300 K.

13. A device for thermoelectric energy harvesting and cooling comprising the polymer composite of claim 1.

14. The device of claim 13, wherein the device comprises modules composed of a plurality of n- and p-type polymer composites connected in series.

15. The device of claim 13, wherein the device is a fabric like material for personal body heat reduction.

16. The device of claim 13, wherein the device is a heat dissipation device for use with microprocessors.

17. A method for synthesizing polymer composites having enhanced thermoelectric properties, comprising:
combining a conducting polymer matrix material with a graphitic carbon filler;
polymerizing the conducting polymer matrix material into a conducting polymer matrix that contains a concentration of graphitic carbon filler; and
optimizing the concentration of graphitic carbon filler by subjecting the conducting polymer matrix to vapor reduction using tetrakis (dimethylamino) ethylene (TDAE) to produce polymer composites, wherein the graphitic carbon filler is dispersed throughout the conducting polymer matrix of the polymer composites in a non-percolated fashion with minimal connections, and wherein the polymer composites have a hole concentration that is reduced relative to the polymer matrix alone or the graphitic carbon filler alone and an electron mobility that is greater than that of the polymer matrix alone or the graphitic carbon filler alone.

18. The method of claim 17, wherein combining the conducting polymer matrix material with graphitic carbon filler comprises spraying the graphitic carbon filler on a substrate and coating the conducting polymer matrix material on the substrate.

19. The method of claim 17, wherein the conducting polymer matrix material is poly(3,4-ethylenedioxythiophene), polyaniline, or mixtures thereof.

20. The method of claim 17, wherein the graphitic carbon filler is carbon nanotubes, graphene nanoribbons, or mixtures thereof.

21. The method of claim 17, wherein the step of polymerizing the conducting polymer matrix material comprises using iron(III) tris-p-toluenesulphonate, iron chloride, or mixtures thereof for oxidation.

22. The method of claim 17, wherein the polymer composites have reduced phononic thermal conductivity and an increased Seebeck coefficient (ZT).

23. The method of claim 17, wherein the graphitic carbon fillers have greater electronic mobility than the conducting polymer matrix, smaller electronic bandgap than the conducting polymer matrix, and an electronic bandgap that is inside a bandgap of the conducting polymer matrix.

24. The method of claim 17, wherein the polymer composites comprise quantum wells.

25. The method of claim 17, wherein the hole concentration of the polymer composites is about 10¹⁸/cm³.

26. The method of claim 17, wherein the electron mobility of the polymer composites is about 14 cm²/Vs.

27. The method of claim 17, wherein the step of optimizing the concentration of graphitic carbon filler comprises subjecting the conducting polymer matrix to vapor reduction using tetrakis (dimethylamino) ethylene (TDAE) until a maximum thermoelectric power factor is reached to produce p-type polymer composites.

28. The method of claim 27, wherein the polymer composites have a Seebeck coefficient (ZT) of about 5 at 300 K.

29. The method of claim 17, wherein the step of optimizing the concentration of graphitic carbon filler comprises subjecting the conducting polymer matrix to vapor reduction using tetrakis (dimethylamino) ethylene (TDAE) until a saturation point is reached to produce n-type polymer composites.

30. The method of claim 29, wherein the polymer composites have a Seebeck coefficient (ZT) of about 2 at 300 K.

31. A layer-by-layer deposition process for a thermoelectric nanocomposite thin film having organic conducting polymers and organic conducting nanomaterials, comprising:
depositing a first polymer layer on a substrate, wherein the first polymer layer includes an organic conducting polymer;
depositing a first nanomaterial layer on the first polymer layer, wherein the first nanomaterial layer includes an organic, conducting two-dimensional (2D) nanomaterial;
depositing a second polymer layer on the first nanomaterial layer, wherein the second polymer layer includes the organic conducting polymer; and
depositing a second nanomaterial layer on the second polymer layer, wherein the second nanomaterial layer includes an organic, conducting one-dimensional (1D) nanomaterial.

32. The process of claim 31, wherein:
depositing the first polymer layer includes applying a first polymer dispersion containing the organic conducting polymer to the substrate;
depositing the first nanomaterial layer includes applying a first nanomaterial dispersion containing the organic, conducting 2D nanomaterial to the substrate;
depositing the second polymer layer includes applying the first polymer dispersion to the substrate; and
depositing the second nanomaterial layer includes applying a second nanomaterial dispersion containing the organic, conducting 1D nanostructure to the substrate.

33. The process of claim 31, further comprising repeating the first polymer layer deposition, the first nanomaterial layer deposition, the second polymer layer deposition, and the second nanomaterial layer deposition until the thin film with desired properties is formed.

34. The process of claim 31, further comprising forming a percolating conductive network with two or more organic conducting polymer layers, one or more organic, conducting 2D nanomaterial layers, and one or more organic, conducting 1D nanomaterial layers.

35. The process of claim 31, wherein the organic, conducting polymer is selected from a group consisting of poly(acetylene)s (PAC), poly(p-phenylene vinylene)s (PPV), poly(pyrrole)s (PPY), polyanilines (PANI), poly(thiophene)s (PT), poly(3,4-ethylenedioxythiophene)s (PEDOT), poly(p-phenylene)s (PPP), and poly(p-phenylene sulfide)s (PPS).

36. The process of claim 34, wherein:
the organic, conducting polymer is polyaniline;
the organic, conductive 1D nanostructure is carbon nanotubes; and
the organic, conductive 2D nanostructure is graphene platelets.

37. The process of claim 32, wherein the first and second organic nanomaterial dispersions contain a stabilizer.
